(19) United States
(12) Patent Application Publication
(10) Pub. No.: US 2021/0135156 A1
(43) Pub. Date: May 6, 2021

(54) DISPLAY DEVICE RESISTANT TO IMPACT

(71) Applicant: Sharp Kabushiki Kaisha, Osaka (JP)

(72) Inventor: Tim Michael Smeeton, Oxford (GB)

(21) Appl. No.: 16/672,786

(22) Filed: Nov. 4, 2019

(51) Int. Cl. H01L 51/52; B32B 5/18; B32B 27/28; B32B 7/12; B32B 27/06

(52) U.S. Cl. CPC H01L 51/5253; B32B 5/18; H01L 27/3244; B32B 7/12; B32B 27/065; B32B 27/281

(57) ABSTRACT

A light-emitting device includes a housing layer, a display located adjacent the housing layer and formed of a plurality of layers including a substrate layer, a window layer formed adjacent the display opposite the housing layer and bonded to the display, and an interface layer that is disposed between the substrate layer and the housing layer and enables a lateral distortion between the display and the housing layer. The interface layer may be configured such that a first resistance to shear between the display and the window is greater than a second resistance to shear between the substrate layer and the housing layer.

### TECHNICAL FIELD

The present invention relates to a light-emitting diode (LED) display device, and more particularly to an LED display device having a layered structure which is configured to improve resilience to damage caused by an impact of an object on the display device.

### BACKGROUND ART

A conventional information display device is formed of a stack of layers that includes, for example, a matrix of organic light-emitting diodes (OLEDs) disposed on a substrate, a touch sensor, and an optical polariser. The layers may be bonded together using adhesive layers. The display device may further be bonded to a window through which the light from the display is emitted. The window also provides a physical protection of the layers in the display. A housing is provided to support the display and provide protection of the layers of the display on the surface opposite to the window and around the edges of the display.

Display devices may be permanently damaged by an impact on the outer surface of the window which is not bonded to another layer of the display. An object may be dropped onto the outer surface of the window and the impact may cause permanent damage to the display device. Even in the event that the window itself is not permanently damaged during the impact, one or more layers of the display may be permanently damaged by transference of the impact force through the window. For example, layers of the display may be permanently damaged if the stress and/or strain within them exceeds a critical value during the impact of the object. Thus, providing a display device that has resilience to impact on the outer surface of the window is desirable.

Prior attempts have been made to improve the resilience of display devices. One prior attempt includes enabling the layers to slip relative to each other in displays which are configured to be bent or folded during use, as set forth in WO 2017/116892 (Everaerts, published Jul. 6, 2017). The '892 Application teaches using a fluid cavity surrounding both sides of the display device to reduce stresses on the display device when bent. Another prior attempt includes adding slippery surfaces between the layers of the display to facilitate displacement of the layers relative to each other during bending, as set forth in U.S. Pat. No. 10,069,100 (Zhang, issued Sep. 9, 2018).

### SUMMARY OF INVENTION

The present disclosure describes a light-emitting diode (LED) display device which includes a housing, a display located above housing and formed of a plurality of layers that includes at least a substrate layer, a window layer that is formed above the display and bonded to the display, and an interface layer that is disposed between the display and the housing. When an object collides with the window, the interface layer enables a lateral displacement of one or more layers of the display relative to the housing and this may be effective in preventing the colliding object from causing permanent damage to one or more layers of the display. The lateral displacement of the display relative to the housing is enabled, for example, by providing an interface material in the interface layer which allows the interface layer to slide relative to the housing or the display. Accordingly, the display device has an improved resilience to damage caused by the impact of the object on the window, such as crack formation in one or more layers of the display.

The interface layer is formed of any suitable material that is configured to provide a low resistance to shear occurring between a lower surface of the display and an upper surface of the housing. The resistance to shear occurring between the display and the housing is lower than a resistance to shear occurring between an upper surface of the display and a lower surface of the window.

In accordance with embodiments of the present invention, the interface material may be bonded to at least one of the upper surface of the housing and to the lower surface of the display using any suitable adhesive material or deposition method. In other exemplary embodiments, the interface material may be bonded to both the housing and the display and have a low stiffness in the lateral direction that enables a lateral displacement of the display and the layers fixed to the display relative to the housing.

In accordance with other exemplary embodiments, the interface material may be unbonded relative to the display and the housing such that a lower surface of the interface material slides or slips over an upper surface of the housing in a lateral direction when subject to a force applied along a direction normal to the lateral direction. In any of the disclosed configurations of the interface material within the display device as disclosed herein, when the display device is subject to a collision type of force in the normal direction relative to the plane of the display device or the lateral direction, a lateral distortion or displacement within the device layers will occur in the lateral direction to prevent permanent damage to one or more layers of the display.

Accordingly, an aspect of the invention is a light-emitting device including a housing layer, a display located adjacent the housing and formed of a plurality of layers including a substrate layer, a window layer formed adjacent the display opposite the housing layer and bonded to the display, and an interface layer that is disposed between the substrate layer and the housing layer and enables a lateral distortion between the display and the housing layer.

In exemplary embodiments, a first resistance to shear between the substrate layer and the window is greater than a second resistance to shear between the substrate layer and the housing. The interface layer may be bonded to at least one of the substrate layer and the housing layer. The interface layer may be formed of a dry lubricant material or a solid lubricant material that is deposited on at least one of the display or the housing. The interface layer may be formed of a fluoropolymer material, a graphite material, or a molybdenum disulphide material. The interface layer may be formed of a particulate material. The interface layer may be formed of a material having a layered crystal structure.

In other exemplary embodiments, the interface layer may be bonded to each of the substrate layer and the housing layer. The interface layer may be formed of a material having a low lateral stiffness, such as a foam material.

In other exemplary embodiments, the interface layer may be formed of a viscous liquid material that adheres to at least one of the display or the housing. The viscous liquid material may be a mineral oil. The interface layer may include a containment wall that contains the viscous liquid material. The interface layer may be formed of a pseudoplastic fluid material, a shear thinning fluid material, a pseudoplastic gel material, or a shear thinning gel material.

In still other exemplary embodiments, the interface layer may be formed of a sheet of material that is unbonded relative to the display and the housing layer and the interface layer is slideable along the housing. The interface layer may be formed of a fluoropolymer material.

The interface layer may have a thickness that is between one and 300 microns. The substrate layer of the display may be formed of a flexible material, such as a polyimide material.

Another aspect of the invention is an electronic device display device having at least one light-emitting device according to any of the embodiments. In such an electronic device, the display may include at least one of a touch sensor layer, a polariser layer, and an adhesive layer.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

FIG. 1 is a drawing depicting an exemplary representation of a conventional light-emitting device.

FIG. 2 is a drawing depicting an exemplary light-emitting device having an interface layer in accordance with embodiments of the present invention prior to a collision of the light-emitting device with an impacting object.

FIG. 3 is a drawing depicting the light-emitting device of FIG. 2 during collision of the light-emitting device with the impacting object.

FIG. 4 is a drawing depicting an exemplary light-emitting device having an interface layer in accordance with embodiments of the present invention in which the lower surface of the interface material slides over an upper surface of a housing of the light-emitting device.

FIG. 5 is a drawing depicting an exemplary light-emitting device having an interface layer in accordance with embodiments of the present invention in which the material of the interface layer is bonded to a display and the housing of the light-emitting device.

FIG. 6 is a drawing depicting a finite element analysis of the light-emitting device in accordance with embodiments of the present invention during a collision with an impacting object.

FIG. 7 is a drawing depicting an exemplary light-emitting device in accordance with embodiments of the present invention in which the interface layer is bonded to the display of the light-emitting device.

FIG. 8 is a drawing depicting an exemplary light-emitting device in accordance with embodiments of the present invention in which the interface layer is unbonded relative to the display and the housing of the light-emitting device.

FIG. 9 is a drawing depicting an exemplary light-emitting device in accordance with embodiments of the present invention in which the interface layer includes a first interface material that is bonded to the display and a second interface material that is bonded to the housing of the light-emitting device.

### DESCRIPTION OF EMBODIMENTS

Embodiments of the present invention will now be described with reference to the drawings, wherein like reference numerals are used to refer to like elements throughout. It will be understood that the figures are not necessarily to scale.

The present disclosure describes a light-emitting diode (LED) display device which includes a housing, a display formed of a plurality of layers including a substrate layer, a window layer that is bonded to the display, and an interface layer that is disposed between the display and the housing and enables a lateral distortion between the display and the housing. When an object collides with the window, the interface layer enables a lateral displacement of one or more layers of the display relative to the housing, and this may be effective in preventing the colliding object from causing permanent damage to one or more layers of the display. The lateral displacement of the display relative to the housing is enabled, for example, by providing an interface material in the interface layer which allows the interface layer to slide relative to the housing or the display. Accordingly, the display device has an improved resilience to damage caused by the impact of the object on the window, such as crack formation in one or more layers of the display.

The interface layer is formed of an interface material that is configured to provide a low resistance to shear occurring between a lower surface of the display and an upper surface of the housing. This resistance to shear is lower than a resistance to shear between an upper surface of the display and a lower surface of the window. As referenced throughout the present disclosure, the resistance to shear is defined as a displacement, such as a sliding movement, between two surfaces when subject to a force that causes a displacement between the surfaces. The present disclosure generally pertains to a force occurring in a direction that is normal or perpendicular to the plane of the surface or surfaces which are displaced, such that the displacement or movement occurs perpendicular relative to the direction of the force. The resistance to shear is inversely proportional to the displacement such that the resistance to shear is low when the displacement between the two surfaces is large for a given force, and the resistance to shear is high when the displacement between the two surfaces is low for the given force.

In an exemplary embodiment, the interface material of the interface layer may be bonded to at least one of the upper surface of the housing and the lower surface of the display. In other exemplary embodiments, the interface material may be bonded to both the housing and the display, and have a low stiffness in the lateral direction that enables a lateral displacement of the display and the layers fixed to the display relative to the housing.

In still other exemplary embodiments, the interface material may be unbonded relative to the display and the housing such that a lower surface of the interface material slides or slips over an upper surface of the housing in a lateral direction when subject to a force applied along a direction normal to the lateral direction.

In any configuration of the interface material within the display device as disclosed herein, when the display device is subject to a collision type of force in the normal direction relative to the plane of the display device or the lateral direction, a lateral distortion or displacement within the device layers will occur in the lateral direction to prevent permanent damage to one or more layers of the display. The lateral distortion may also be referred to as a lateral spreading.

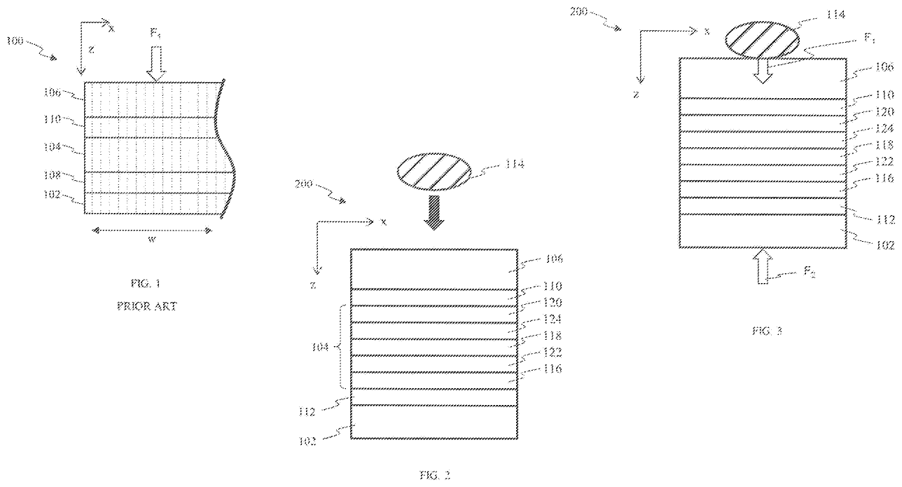

FIG. 1 is a drawing depicting a conventional display device 100 having a plurality of adjacent layers. The conventional display device 100 includes a housing 102 that is arranged as an end layer or bottom layer of the display device 100, and a display 104 that is arranged adjacent the housing 102 and includes a plurality of layers. The display may include a transmissive or emissive imaging material that emits light to display content to a user. A window 106 is arranged adjacent the display 104 opposite the housing 102. The window 106 is an end layer or upper layer of the display device 100. The display device 100 may include adhesive layers 108, 110. An adhesive layer 110 is provided between the display 104 and the window 106. An adhesive layer 108 may be provided between the display 104 and the housing 102. The adhesive layer 108 results in a resistance to shear between the display 104 and the housing 102. Alternatively, the display 104 and the housing 102 may not be bonded together and in this case, when the lower surface of the display 104 and the upper surface of the housing 102 are in contact, a frictional force exists between said surfaces which results in a resistance to shear between the display 104 and the housing 102.

During a collision of an object against the window 106 of the conventional display device 100, a force F₁ may be applied to the window 106 in a direction that is normal or perpendicular to the width w of the display device 100, such as in a positive z-direction, as shown in FIG. 1. Consequently, due to a Poisson effect, a deformation or strain occurs in a lateral direction, or x-direction as shown in FIG. 1, which is also the direction in which the width w of the display device 100 extends. The material of the housing 102 may be rigid, such that the lateral deformation of the housing is small. Consequently, a similarly small lateral deformation may occur in each of the separate layers of the display 104 due to the large resistance to shear between the display 104 and housing 102. In the case that an adhesive layer 108 bonds the display 104 to the housing 102, the resistance to shear of the adhesive layer 108 results in the small lateral deformation of the housing constraining the lateral deformation of the display 104. In the case that the display 104 and housing 102 are not bonded together, the force F₁ in the positive z-direction acts to push the lower surface of the display 104 and the upper surface of the housing 102 together and thereby creates a large frictional force which causes a large resistance to shear during the collision of the object against the window and the lateral deformation 104 of the display is similarly constrained.

Referring now to FIGS. 2-9, a display device 200 according to the present application includes the housing 102, the display 104, the adhesive layer 110, and the window 106 as previously described, and further includes an interface layer 112 arranged between the housing 102 and the display 104. The window 106 may be formed of any suitable material such as a glass material or a polymer film material. The interface layer 112 is formed of a material that is configured to provide a lower resistance to shear between the display 104 and the housing 102 as compared with the conventional display device 100, such that the resilience of the display device 200 to damage during impact of an object 114 (shown in FIGS. 2 and 3) on the window 106 is improved. In particular, the resilience of one or more layers of the display 104 to damage during impact of an object 114 on the window 106 is improved.

In reference to directions, references to a bottom or lower element of the display device stack of any of the embodiments corresponds to a non-viewing side, and references to a top or upper element of the display device stack of any of the embodiments corresponds to a viewing side through which image light is emitted. Accordingly, the layers of display device 200, as representative, as ordered from the viewing side include the window 106, the display 104 with the substrate 116 being the non-viewing side layer of the display 104, the interface layer 112, and the housing 102. In addition, references to layers being adjacent to each other may exclude the adhesive layers (e.g., layer 110), as such adhesive layers generally perform a bonding function between two layers identified as adjacent.

The interface layer 112 extends in the x-direction or plane of the display device 200 and may extend along an entire width and/or length of the display device 200. In exemplary embodiments, the interface layer 112 may extend along a partial width and/or length of the display device 200. For example, the display device 200 may be flexible or bendable, such that the interface layer 112 is only arranged in areas of the display device 200 which are rigid and non-bendable. The interface layer 112 may have any suitable thickness. For example, the interface layer 112 may have a thickness that is between one and 300 microns. The thickness of the interface layer 112 may be similar to the thicknesses of other layers within the display 104 and less than the thickness of the housing 102 and the window 106.

The display 104 is formed of a plurality of layers including at least a substrate layer 116 on which any suitable pixel structure is formed. The substrate layer 116 is the layer of the display 104 that is nearest to the housing 102 and adjacent the interface layer 112. In an exemplary embodiment, the pixel structure formed on the substrate layer 116 may include an array of organic light-emitting diodes (OLEDs) which are operable as an active matrix display by way of circuits comprising thin film transistors (TFT) which are disposed on the substrate layer 116. The display device 200 may include any other suitable display that is disposed on the substrate layer 116. Examples of other suitable displays include quantum dot LED displays in which light emission is by electroluminescence from nanocrystal quantum dot materials disposed on the substrate layer 116. The substrate layer 116 may be formed of any suitable flexible material which enables the display device 200 to be bendable or flexible. Providing a flexible material may be particularly suitable for use in OLED displays, and an example of a suitable flexible material is a polyimide material. The substrate layer 116 may further comprise a shock absorbing element. A suitable shock absorbing element can be elastically (reversibly) deformed in the vertical direction (z-direction in FIG. 2) during impact of an object 114 on the window 106 which is bonded to the display 104. The substrate layer 116 may further comprise a heat-dissipating element. A suitable heat dissipating element has a high thermal conductivity which is effective at conducting heat laterally (e.g. in x-direction) and thereby preventing a portion of the display 104 from becoming a significantly different temperature to another portion of the display 104.

The plurality of layers of the display 104 may include any suitable number of layers that enhance the quality of the emitted image and display interface operations. In an exemplary embodiment of the display 104, the display 104 includes at least one of a touch sensor layer 118, an optical polariser layer 120, and multiple adhesive layers 122, 124 that are arranged between two adjacent layers for bonding. The touch sensor layer 118 may be a capacitive touch sensor formed from electrodes that are deposited on a polymer sheet, or any other suitable touch sensor. The optical polariser layer 120 may be a circular polariser, and the adhesive layers 122, 124 may have a low light absorption for light emitted from the display 104 and refractive indices that are similar to the layers which are being bonded by the adhesive layers 122, 124. For example, the adhesive layers 122, 124 may be formed of an indexed-matched optically clear adhesive. The layers of the display 104 are stacked in any suitable order or arrangement and in exemplary embodiments, the uppermost layer of the display 104 may be the optical polariser layer 120 and the bottommost layer of the display 104 may be the substrate layer 116.

FIGS. 2 and 3 show the collision of the impacting object 114 with the display device 200. As shown in FIG. 2, the impacting object 114 moves toward the window 106 in the z-direction which is perpendicular or normal to the plane of the window 106. As shown in FIG. 3, the impacting object 114 comes into contact with the window 106 and applies the force F₁ in the z-direction. In response to the force F₁ in the positive z-direction, a reactive force F₂ in the negative z-direction occurs resulting in a compressive stress in the window 106 and the display 104 in the z-direction. Even in a case that the display 104 is not initially in contact with the housing 102 (e.g. if the display 104 is not bonded to the housing 106 by an adhesive layer 108), the display 104 and window 106 are deformed by the force F₁ until the display 104 is in contact with the housing 106 and then the reactive force F₂ occurs.

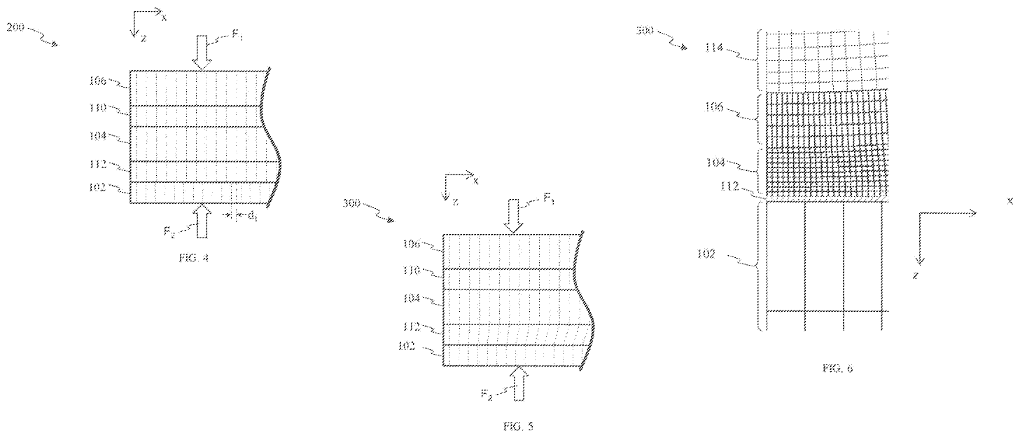

As shown in FIG. 4, in an exemplary embodiment of the display device 200, the interface layer 112 is formed of an interface material that is configured to provide the low resistance to shear. As shown in FIG. 4, the interface layer 112 may be bonded to a non-viewing side surface or bottom surface of the display 104, which means the interface layer 112 is bonded to the substrate layer 116 of the display 104 depicted in FIGS. 2 and 3. The lower surface of the interface layer 112 slides or slips over the upper surface of the housing 102 in the lateral direction or x-direction, such that the lower surface of the interface layer 112 is laterally shifted and has a lateral distortion or lateral displacement d₁ relative to the housing 102. Another lateral displacement may also occur simultaneously in another lateral direction that is also within the plane of the interface layer 112 and perpendicular to the direction of the x-direction, such as in a y-direction. The displacement of the interface layer 112 is perpendicular to the direction of the applied stress or the force F₁ as caused by the Poisson effect.

In FIG. 4, vertical dashed grid lines are used to illustrate lateral displacement between the display 104 and the housing 102. The vertical dashed grid lines indicate regions which were aligned prior to application of the force F₁ such that misalignment of the dashed grid lines indicates lateral displacement (e.g. d₁). For example, in case of impact of an object with a radial symmetric shape about the z-direction, the left edge of FIG. 4 corresponds to the region of the display device 200 below the centre of the object—where the lateral displacement in the x-direction is zero—and the positive x-direction is a radial direction.

FIG. 5 shows another exemplary embodiment of a display device 300 in which the interface layer 112 is bonded to both the upper surface of the housing 102 and to the lower surface (substrate layer 116) of the display 104. In the display device 300, the interface layer 112 may be formed of a material having a low stiffness in the lateral direction such that the interface layer 112 has a low resistance to shear in the lateral direction. Any suitable low stiffness material may be used, such as a foam material or an elastomeric material with low stiffness. For example, an acrylic foam material may be suitable. When the force F₁ of the impacting object is applied in the positive z-direction, the interface layer 112 deforms with a shear strain in the lateral direction. The shear strain deformation may be in the form of displacement of the top of the interface layer 112 relative to the bottom of the interface layer 112, as shown by the inclined dotted lines shown in FIG. 5. For example, in case of impact of an object with a radial symmetric shape about the z-direction, the left edge of FIG. 5 corresponds to the region of the display device 300 below the centre of the object—where the lateral displacement in the x-direction is zero—and the positive x-direction is a radial direction. The degree of incline of the dotted lines may increase in the positive x-direction.

In the examples of FIG. 4 and FIG. 5, the lateral displacement of the display 104, adhesive layer 110 and window 106 are shown to be equal. It should be understood that this is just an example of one possibility. In particular, the lateral displacement may be different in these layers. Furthermore, the lateral displacement within different layers within the display 104 may be different.

As shown in both FIGS. 4 and 5, the lateral distortions of the interface layer 112 within the device 200, 300 are similar in either arrangement. During impact of the object 114 against the window 106 of the display device 200, 300, the interface material of the interface layer 112 enables the lateral displacement d₁ (FIG. 4) or distortion of the interface layer 112 (FIG. 5). This displacement or distortion of the interface layer 112 can change the distribution of stresses and strains within the layers of the display 104 such that advantageously permanent damage to one or more layers of the display 104 can be prevented during impact of the object 112.

In one example, the lateral displacement facilitated by the interface layer 112 can enable a shock absorbing element within the display 104 to undergo larger vertical deformation for a given impact force in the vertical direction. When a force is applied to a shock absorbing element in a vertical direction (z-direction) the compressive strain in the vertical direction is lower if the shock absorbing element is constrained in the lateral direction than if it is not constrained. Therefore, if the lateral displacement of the lower surface of the display 104 is facilitated by the interface layer 112, a shock absorbing element in the display 104 may exhibit larger vertical displacement during the impact of an object 114. During impact of the object 114 on the window 106, the window 106 may elastically (reversibly) deform in the direction of motion of the object 114. The kinetic energy of the object 106 is partially converted into energy associated with the elastic deformation of the window 106. A larger compressive strain in the vertical direction in a shock absorbing element can therefore facilitate a larger elastic deformation of the window 106, absorbing a larger amount of energy associated with the elastic deformation of the window 106. Absorption of more energy of the impact in the window 106 may contribute to lower stress and strain in critical layers of the display 104 and therefore prevent damage to said critical layers. The interface layer 112 therefore enables a larger elastic deformation of a window 106 without requiring an increase in thickness of a shock absorbing element.

FIG. 6 is a drawing depicting a finite element analysis simulation of the impact of the object 114 when dropped on the window 106 of the display device 300 shown in FIG. 5 in which the interface layer 112 is adhered to both the display 104 and the housing 102. For example, the object 114 may be a ball formed of a hard material such as a metal material for purposes of the simulation, although comparable results may be achieved for other impacting objects. In addition, the notion of an impacting motion is relative such that an object may move to impact the display device or the display device my move to impact the object (e.g., dropping one's portable display device).

In the simulation of FIG. 6, each of the window 106, the display 104, and the interface layer 112 are shown to have grid lines. Prior to the impact of the object 114 on the window 106, the grid lines of the layers 104, 106, 112 are substantially horizontal and vertical relative to the housing 102. After the impact of the object 114, the grid lines of the interface layer 112 are inclined in the lateral direction, or in the x-direction, showing the lateral distortion of the interface layer 112. The distortion of the grid lines in the display 104 and the window 106 is caused by the lateral distortion of the interface layer 112. The lateral distortion is enabled by a low resistance to shear caused by the low resistance to shear of the material of the interface layer 112 that has low lateral stiffness. Accordingly, one or more layers of the display 104 has a lateral expansion or spreading and damage to layers of the display 104 can be avoided.

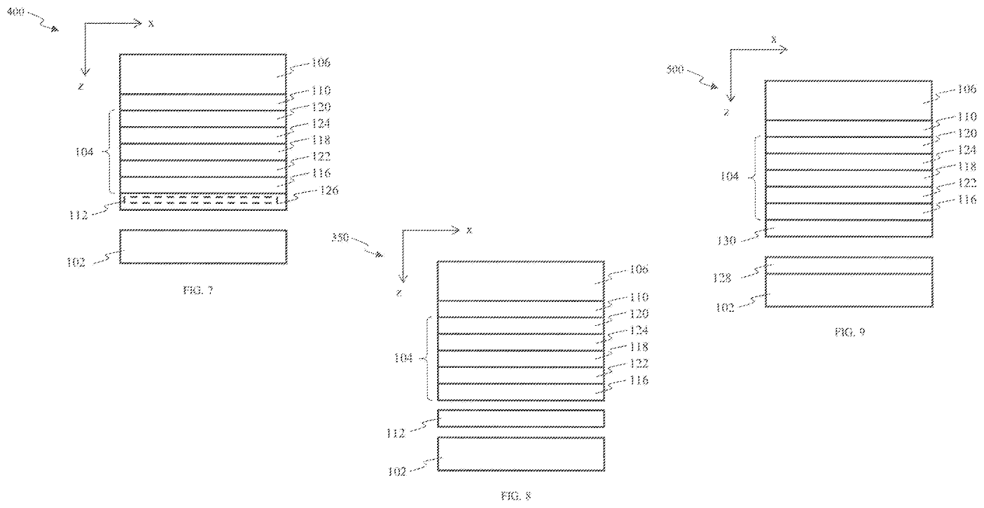

Referring now to FIGS. 7-9, exemplary embodiments of a display device 350, 400, and 500 are shown. As shown in FIG. 7, an exemplary embodiment of the display device 400 includes the interface layer 112 being bonded to at least one of the display 104 and the housing 102. As shown in FIG. 7, the interface layer 112 may be bonded to the lower surface of the display 104, or the substrate layer 116 of the display 104, and unbonded relative to the housing 102. In other exemplary embodiments, the interface layer 112 may be bonded to the upper surface of the housing 102 and unbonded relative to the display 104. The bonding between the interface layer 112 and at least one of the display 104 and the housing 102 may include providing an adhesive layer or using any suitable gluing or deposition method for depositing the material of the interface layer 112 on the corresponding surface. Examples of suitable deposition methods include liquid or vapour deposition.

The interface layer 112 in the display device 400 may be formed of any suitable material. For example, a suitable material may be a dry lubricant or a solid lubricant material that is deposited onto at least one of the lower surface of the display 104 or the upper surface of the housing 102. Using a solid lubricant may be particularly advantageous in that solid lubricants may have a more consistent friction value over a wider range of operating temperatures of the display device 400. Additionally, a solid lubricant may be more easily applied and incorporated into the display device 400. Examples of suitable lubricant materials include a fluoropolymer material, graphite, and molybdenum disulphide. Polytetrafluoroethylene may be suitable. In exemplary embodiments, the interface material may be a particulate material or a material having a layered crystal structure.

In other exemplary embodiments, the interface material of the interface layer 112 may be in the form of any suitable liquid material, such as a viscous liquid material which adheres to at least one of the lower surface of the display 104 or the upper surface of the housing 102 and does not flow off of the surface during operating temperatures of the display device 300. A mineral oil material may be suitable. Using an oil material may be particularly advantageous in that the oil may have a consistently low resistance to shear over a wide range of operating temperatures of the display device 400. The resistance to shear may also remain low when the stress due to the collision with the window 106 is high.

In an exemplary embodiment in which the interface material is a liquid material, the interface layer 112 may further include a containment structure 126 for retaining the liquid material, such as a vertically-extending wall, barrier, or other suitable structure. The containment structure 126 may be used to prevent the liquid from being transported from outside of the interface layer 112. Using the liquid material may be further advantageous in that the liquid provides a barrier to the ingress of oxygen or water into the display device 400, such that the performance and lifetime of the display device 400 is enhanced.

In other exemplary embodiments, the interface material may be a gel, or another interface material that has shear thinning properties. Accordingly, the resistance to shear may be reduced as the change in the shear strain, or shear strain rate is increased, such as during the collision on the window 106 of the display device 300. Examples of suitable materials include a pseudoplastic fluid material, a shear thinning fluid material, a pseudoplastic gel material, or a shear thinning gel material. In this case, the interface layer 112 may advantageously provide low resistance to shear during an impact but higher resistance to shear at other times. Referring to the example described above that the low resistance to shear in the interface layer 112 may facilitate a large vertical deflection of a shock absorbing element in the display 104 during an impact, if the interface material of the interface layer 112 has shear thinning properties, the vertical deflection of the shock absorbing element may be lower during routine operation of the display device—for example providing a low vertical deflection when a user touches the window 106 during conventional operation of the touch sensor of a display and the strain rate is low—but provide advantageously large vertical compression during an impact where the strain rate is high.

As shown in FIG. 8, another exemplary embodiment of the display device 350 includes the interface layer 112 being unbonded relative to both the housing 102 and the display 104, as also shown in FIG. 4. In the exemplary embodiment of the display device 350, the interface layer 112 may be formed of any suitable material and may be in the form of a thin sheet of material that is able to slide or slip between the display 104 and the housing 102 to provide the lateral distortion within the display device 350. An example of a suitable material is a fluoropolymer material, such as polytetrafluoroethylene. Other comparable materials may be suitable.

As shown in FIG. 9, another exemplary embodiment of the display device 500 includes the interface layer being formed of a first interface material 128 and a second interface material 130 that are vertically stacked and adjacent relative to each other. The first interface material 128 may be bonded to the lower surface of the display 104, such as the substrate layer 116. The second interface material 130 may be bonded to the upper surface of the housing 102. The first interface material 128 and the second interface material 130 may be unbonded relative to each other. The first interface material 128 and the second interface material 130 may be formed of the same material or different materials. The interface materials may enable sliding or slipping between the first interface material 128 and the second interface material 130. In other exemplary embodiments, the interface materials may be bonded to each other.

An aspect of the invention is a light-emitting device including a housing layer, a display located adjacent the housing layer and formed of a plurality of layers including a substrate layer, a window layer formed adjacent the display opposite the housing layer and bonded to the display, and an interface layer that is disposed between the substrate layer and the housing layer and enables a lateral distortion between the display and the housing layer.

In an exemplary embodiment of the light-emitting device, a first resistance to shear between the display and the window is greater than a second resistance to shear between the substrate layer and the housing layer.

In an exemplary embodiment of the light-emitting device, the interface layer is bonded to at least one of the substrate layer and the housing layer.

In an exemplary embodiment of the light-emitting device, the interface layer is bonded to each of the substrate layer and the housing layer.

In an exemplary embodiment of the light-emitting device, the interface layer is formed of a material having a low lateral stiffness.

In an exemplary embodiment of the light-emitting device, the interface layer is formed of a foam material.

In an exemplary embodiment of the light-emitting device, the interface layer is formed of a dry lubricant material or a solid lubricant material that is deposited on at least one of the display or the housing layer.

In an exemplary embodiment of the light-emitting device, the interface layer is formed of a fluoropolymer material, a graphite material, or a molybdenum disulphide material.

In an exemplary embodiment of the light-emitting device, the interface layer is formed of a particulate material.

In an exemplary embodiment of the light-emitting device, the interface layer is formed of a material having a layered crystal structure.

In an exemplary embodiment of the light-emitting device, the interface layer is formed of a viscous liquid material that adheres to at least one of the display or the housing layer.

In an exemplary embodiment of the light-emitting device, the viscous liquid material is a mineral oil.

In an exemplary embodiment of the light-emitting device, the interface layer includes a containment wall that contains the viscous liquid material.

In an exemplary embodiment of the light-emitting device, the interface layer is formed of a pseudoplastic fluid material, a shear thinning fluid material, a pseudoplastic gel material, or a shear thinning gel material.

In an exemplary embodiment of the light-emitting device, the interface layer is formed of a sheet of material that is unbonded relative to the display and the housing layer, and the interface layer is slideable along the housing layer.

In an exemplary embodiment of the light-emitting device, the interface layer is formed of a fluoropolymer material.

In an exemplary embodiment of the light-emitting device, the interface layer has a thickness that is between one and 300 microns.

In an exemplary embodiment of the light-emitting device, the substrate layer is formed of a flexible material.

In an exemplary embodiment of the light-emitting device, the substrate layer is formed of a polyimide material.

In an exemplary embodiment of the light-emitting device, an electronic device includes at least one light-emitting device in which the display includes at least one of a touch sensor layer, a polariser layer, and an adhesive layer.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

### INDUSTRIAL APPLICABILITY

The present invention relates to LED devices that, for example, may be used for light-emitting elements in a display device. Embodiments of the present invention are applicable to many display devices to permit display devices of high resolution and high image quality. Examples of such devices include televisions, mobile phones, personal digital assistants (PDAs), tablet and laptop computers, desktop monitors, digital cameras, and like devices for which a high resolution display is desirable.

### REFERENCE SIGNS LIST

100—conventional display device
102—housing
104—display
106—window
108—adhesive layer
110—adhesive layer
112—interface layer
114—object that impacts display
116—substrate layer
118—touch sensor layer
120—optical polariser layer
122—adhesive layer
124—adhesive layer
126—containment structure
128—first interface material
130—second interface material
200—display device
300—display device
350—display device
400—display device
500—display device

1. A light-emitting device comprising:
a housing layer;
a display located adjacent the housing layer and formed of a plurality of layers including a substrate layer;
a window layer formed adjacent the display opposite the housing layer and bonded to the display; and
an interface layer that is disposed between the substrate layer and the housing layer and enables a lateral distortion between the display and the housing layer.

2. The light-emitting device of claim 1, wherein a first resistance to shear between the display and the window is greater than a second resistance to shear between the substrate layer and the housing layer.

3. The light-emitting device of claim 1 or 2, wherein the interface layer is bonded to at least one of the substrate layer and the housing layer.

4. The light-emitting device of claim 3, wherein the interface layer is bonded to each of the substrate layer and the housing layer.

5. The light-emitting device of claim 4, wherein the interface layer is formed of a material having a low lateral stiffness.

6. The light-emitting device of claim 5, wherein the interface layer is formed of a foam material.

7. The light-emitting device of claim 1, wherein the interface layer is formed of a dry lubricant material or a solid lubricant material that is deposited on at least one of the display or the housing layer.

8. The light-emitting device of claim 7, wherein the interface layer is formed of a fluoropolymer material, a graphite material, or a molybdenum disulphide material.

9. The light-emitting device of claim 7, wherein the interface layer is formed of a particulate material.

10. The light-emitting device of claim 7, wherein the interface layer is formed of a material having a layered crystal structure.

11. The light-emitting device of claim 1, wherein the interface layer is formed of a viscous liquid material that adheres to at least one of the display or the housing layer.

12. The light-emitting device of claim 11, wherein the viscous liquid material is a mineral oil.

13. The light-emitting device of claim 11, wherein the interface layer includes a containment wall that contains the viscous liquid material.

14. The light-emitting device of claim 1, wherein the interface layer is formed of a pseudoplastic fluid material, a shear thinning fluid material, a pseudoplastic gel material, or a shear thinning gel material.

15. The light-emitting device of claim 1, wherein the interface layer is formed of a sheet of material that is unbonded relative to the display and the housing layer, and the interface layer is slideable along the housing layer.

16. The light-emitting device of claim 15, wherein the interface layer is formed of a fluoropolymer material.

17. The light-emitting device of claim 1, wherein the interface layer has a thickness that is between one and 300 microns.

18. The light-emitting device of claim 1, wherein the substrate layer is formed of a flexible material.

19. The light-emitting device of claim 1, wherein the substrate layer is formed of a polyimide material.

20. An electronic device comprising at least one light-emitting device according to claim 1, wherein the display includes at least one of a touch sensor layer, a polariser layer, and an adhesive layer.
